(19) United States
(12) Patent Application Publication
(10) Pub. No.: US 2026/0327799 A1
(43) Pub. Date: Oct. 22, 2026

(54) AN ATOMIC LAYER DEPOSITION APPARATUS AND A METHOD

(71) Applicant: BENEQ OY, Espoo (FI)

(72) Inventors: Lassi LEPPILAHTI, Espoo (FI); Tomi KEMPPAINEN, Espoo (FI)

(21) Appl. No.: 19/491,522

(22) PCT Filed: Jun. 7, 2024
(86) PCT No.: PCT/FI2024/050298

§ 371 Date: Dec. 9, 2025

(30) Foreign Application Priority Data
Jun. 9, 2023 (FI) 20235650

(51) Int. Cl. C23C 16/455

(52) U.S. Cl. CPC C23C 16/45544; C23C 16/45555

(57) ABSTRACT

Please replace the Abstract of the Disclosure with the rewritten Abstract of the Disclosure located below:

An atomic layer deposition apparatus for coating an inner surface of a substrate tube includes a first gas connection fitting arranged to receive a first end of the substrate tube and to connect the substrate tube from its first end to the apparatus, a second gas connection fitting arranged to receive a second end of the substrate tube and to connect the substrate tube from its second end to the apparatus, an inlet tube arranged to supply the first precursor and the second precursor, and an outlet tube arranged to discharge the first precursor and the second precursor that have been supplied through the substrate tube.

### FIELD OF THE INVENTION

The present invention relates to an atomic layer deposition apparatus for processing an inner surface of a substrate tube.

The present invention also relates to a method for subjecting an inner surface of a substrate tube to successive surface reactions of at least a first precursor and a second precursor, and more particularly to a method as defined in the preamble of the independent claim 8.

### BACKGROUND OF THE INVENTION

In the prior art substrate tubes are coated in an atomic layer deposition apparatus such that they are placed inside a reaction chamber and the precursors are supplied to the reaction chamber reaching the substrate tube placed in the reaction chamber.

However, this kind of coating process provides coating also to all other surfaces of the substrate tube and not just the inner surface of the substrate tube. Also, the inner surface may not be completely coated because when the substrate tube is relatively small in diameter and sufficiently long, the precursor may not reach the whole length of the substrate tube and thereby coating is not formed on the entire inner surface of the substrate tube.

### BRIEF DESCRIPTION OF THE INVENTION

An object of the present invention is to provide an atomic layer deposition apparatus and a method for subjecting an inner surface of a substrate tube for successive surface reactions of at least a first precursor and a second precursor which at least alleviates the prior art problems.

The objects of the invention are achieved by an atomic layer deposition apparatus and a method for subjecting an inner surface of a substrate tube which are characterized by what is stated in the independent claims. The preferred embodiments of the invention are disclosed in the dependent claims.

The invention is based on the idea of providing an atomic layer deposition apparatus to which a substrate tube to be coated on the inner surface can be connected so that each substrate tube forms its own reaction chamber of the atomic layer deposition apparatus. Thereby the atomic layer deposition apparatus according to the invention only comprises a reaction chamber or multiple reaction chambers when the substrate tubes are connected to the apparatus.

An atomic layer deposition apparatus according to the invention for processing an inner surface of a substrate tube successively with at least a first precursor and a second precursor according to principles of atomic layer deposition comprises a first gas connection fitting arranged to receive a first end of the substrate tube and to connect the substrate tube from its first end to the apparatus. The apparatus further comprises a second gas connection fitting arranged to receive a second end of the substrate tube and to connect the substrate tube from its second end to the apparatus. The apparatus further comprises an inlet tube arranged to supply the first precursor and the second precursor from corresponding gas sources into the substrate tube. The first gas connection fitting being in a flow communication both with the inlet tube and the substrate tube and providing a flow communication between the inlet tube and the substrate tube. And the apparatus also comprises an outlet tube arranged to discharge the first precursor and the second precursor that have been supplied through the substrate tube. The second gas connection fitting being in a flow communication both with the outlet tube and the substrate tube and providing a flow communication between the substrate tube and the outlet tube.

In other words, the atomic layer deposition apparatus according to the invention comprises an inlet tube arranged to supply the precursors from corresponding gas sources, and an outlet tube arranged to discharge the precursors supplied from the inlet tube out of the apparatus, and gas connection fittings arranged in connection with the inlet tube and the outlet tube, and arranged to connect the substrate tube to the atomic layer deposition apparatus to form a flow path for the precursors from the inlet tube to the outlet tube. The gas connection fittings may not be directly connected to the inlet tube or to the outlet tube, but they are arranged in connection with the inlet tube and the outlet tube to provide a flow communication from the inlet tube through the first gas connection fitting to the substrate tube connected to the first gas connection fitting and further to provide a flow communication from the substrate tube connected to the second gas connection fitting through the second gas connection fitting to the outlet tube. The precursors supplied from the gas sources through the inlet tube are therefore supplied through the substrate tube having a first end and a second end which the first end is connected to the first gas connection fitting and the second end is connected to the second gas connection fitting. The substrate tube having a first open end and a second open end and a channel extending between the first end and the second end.

The first end and the second end of the substrate tube may comprise a flange arrangement for connecting the substrate tube to the first gas connection fitting and to the second gas connection fitting. This is advantageous especially in situations where the substrate tube is other than a straight tubular tube. In the context of this application, the substrate tube is to be understood as a tube which has a first end opening and a second end opening and a channel extending between the first end opening and the second end opening. The substrate tube may have any form such as a straight tube, a helicoidal tube, a bent tube, or any combination of these, just to give some examples.

As described earlier the first gas connection fitting is arranged to receive the first end of the substrate tube and to connect the substrate tube from its first end to the apparatus and the second gas connection fitting is arranged to receive the second end of the substrate tube and to connect the substrate tube from its second end to the apparatus. However, the first end of the substrate tube and the second end of the substrate tube do not necessarily comprise the end openings of the substrate tube, but the substrate tube can have a common adapter for connecting the substrate tube to the gas connection fitting such that the common adapter connects several substrate tubes and forms a common channel for them to be connected to the gas connection fitting. Alternatively, a single substrate tube may comprise a flange type connector at the end of the substrate tube to be connected to the gas connection fitting. According to the invention the apparatus further comprising a first gas manifold having at least two first gas connection fittings for connecting corresponding amount of substrate tubes to the apparatus, and a second gas manifold having at least two second gas connection fittings for connecting corresponding amount of substrate tubes to the apparatus. The first gas manifold being provided in a flow communication with the inlet tube for supplying the first precursor and the second precursor from the gas sources through the inlet tube into the substrate tubes, and the second gas manifold being provided in a flow communication with the outlet tube for discharging the first precursor and the second precursor that have been supplied through the substrate tube.

In other words, the first gas connection fittings are arranged at a first gas manifold which divides the precursor flow coming from the inlet tube into several precursor flows flowing into the substrate tubes. The first gas manifold therefore divides the one precursor gas line in the form of the inlet tube into several precursor gas lines in the form of the substrate tubes connected to the first gas manifold through the first gas connection fittings. The substrate tubes are connected to the first gas connection fittings from their first ends, and they are connected to the second gas connection fittings from their second ends. The second gas connection fittings are arranged at the second gas manifold which then collects the gas lines in the form of the substrate tubes into one common gas line in the form of the outlet tube.

The substrate tubes connected to the first gas manifold and the second gas manifold are arranged to extend side by side between the first gas manifold and the second gas manifold. The substrate tubes can also be arranged at different levels in relation to each other in the vertical direction of the device, or there can be several levels of side by side extending substrate tubes between the first gas manifold and the second gas manifold.

The substrate tubes that are arranged to extend between the first and second gas manifolds and which are connected to the first and second gas manifolds have preferably a diameter in a range between ⅛ inch and 1 inch, and most preferably in a range between ¼ inch and ½ inch. Also, substrate tubes having larger diameter can be coated from their inner surfaces in the apparatus according to the invention. However, substrate tubes having larger diameter can be coated successfully in a normal reaction chamber of an atomic layer deposition apparatus.

The first gas connection fittings of the first gas manifold and the second gas connection fittings of the second gas manifold may comprise extensions to arrange the fittings a distance from said gas manifold. This way, when the gas manifolds are fixed to the apparatus, substrate tubes of different lengths can be connected to the apparatus, or when the substate tubes are of such a size that they do not fit next to each other, extensions can be used to make the substrate tubes to fit without having to modify the gas manifold itself. According to the invention the substrate tube connected to the apparatus with the first gas connection fitting and the second gas connection fitting and extending between the first gas connection fitting and the second gas connection fitting is arranged to form a reaction chamber of the atomic layer deposition apparatus.

In other words, the atomic layer deposition apparatus of the invention does not require a conventional reaction chamber, but the substrate tube connected from its ends to the apparatus forms the reaction chamber. The substrate tube is connected to the apparatus with the connection to the first gas connection fitting and the second gas connection fitting which are preferably VCR fittings offering a metal-to-metal seal which is leak tight.

According to the invention the apparatus further comprises an adapter module arranged to be placed between the first gas connection fitting and the second gas connection fitting in the apparatus to enable connecting of substrate tubes successively between the first and second gas connection fittings, the adapter module having corresponding gas connection fittings for the substrate tubes and provides a flow path for supplying precursors from the inlet tube through the adapter module to the outlet tube when the substrate tubes are connected to the gas connection fittings.

In other words, the adapter module is arranged to provide more substrate tubes to the apparatus for simultaneous coating of the inner surfaces of the substrate tubes. Thereby, the adapter module is arranged between the first and second gas manifolds and provides similar gas connection fittings as the first and second gas manifold. The adapter module having the second gas connection fittings facing toward the first gas connection fittings of the first gas manifold, and the adapter module having the first gas connection fittings at the opposite side of the adapter module than the second gas connection fittings, which the first gas connection fittings of the adapter module facing toward the second gas connection fittings of the second gas manifold. The adapter module provides a flow path inside the adapter module between the second gas connection fittings and the first gas connection fittings such that the precursor flow from the inlet tube through first gas manifold and the substrate tube flows through the adapter module to the successive substrate tube and finally through the second gas manifold to the outlet tube.

According to the invention the apparatus further comprises a vacuum chamber comprising interface connections for the inlet tube and for the outlet tube.

In other words, the vacuum chamber is provided to surround the reaction chamber assembly which is formed of the at least one substrate tube connected to the inlet tube and the outlet tube through at least the first gas connection fitting and the second gas connection fitting. Therefore, the vacuum chamber comprises interface connections for the inlet tube and for the outlet tube at which the inlet tube and the outlet tube connects when the apparatus is set to operate.

According to the invention the apparatus further comprises a frame structure, and the inlet tube being in the flow communication with the first gas connection fitting, and the outlet tube being in the flow communication with the second gas connection fitting are arranged in a frame structure.

In other words, the inlet tube and the outlet tube are arranged in connection with a frame structure and the frame structure extends at least between the inlet tube and the outlet tube such that the substrate tube or substrate tubes arranged between the inlet tube and the outlet tube are on the frame structure. The frame structure preferably comprises a support surface extending on the frame structure so that the adapter module can be provided on the support surface or the substrate tubes being long and small in diameter may bend and rest on the support surface.

According to the invention the frame structure is arranged to be movable so that it can be moved into and out of the vacuum chamber.

In other words, the frame structure comprises means of movement such as wheels or rail system such that the frame comprising the inlet tube and outlet tube together with gas connection fittings and substrate tubes can be moved into the vacuum chamber for processing and out from the vacuum chamber when the atomic layer deposition process is completed.

Method for subjecting an inner surface of a substrate tube according to the invention to successive surface reactions of at least a first precursor and a second precursor according to principles of atomic layer deposition in an atomic layer deposition apparatus for forming a coating to the inner surface of the substrate tube comprises the following steps: providing the substrate tube to the apparatus and connecting the substrate tube from its first end to a first gas connection fitting provided in a flow communication with an inlet tube and from its second end to a second gas connection fitting provided in a flow communication with an outlet tube; and forming a coating to the inner surface of the substrate tube by: subjecting the inner surface of the substrate tube with the first precursor by supplying the first precursor from the inlet tube through the substrate tube and discharging the first precursor supplied through the substrate tube to the outlet tube; and subjecting the inner surface of the substrate tube with the second precursor by supplying the second precursor from the inlet tube through the substrate tube and discharging the second precursor supplied through the substrate tube to the outlet tube.

In other words, at least one substrate tube is connected to the apparatus such that the first open end of the substrate tube is connected to the first gas connection fitting and the second open end of the substrate tube is connected to the second gas connection fitting. The first and second gas connection fittings connect the substrate tube to the apparatus and form a flow connection between the inlet tube and the substrate tube and further a flow connection between the substrate tube and the outlet tube. The substate tube connected at its both ends to the apparatus forms a reaction chamber of the atomic layer deposition apparatus of the invention. The coating to the inner surface of the substrate tube connected to the apparatus is formed by supplying the first precursor from the inlet tube through the substrate tube and discharging the first precursor through the outlet tube and then supplying the second precursor similarly, i.e., supplying the second precursor from the inlet tube through the substrate tube and discharging the second precursor through the outlet tube. Thereby the coating is formed all over the inner surface of the substrate tube.

According to the invention the atomic layer deposition apparatus comprising a first gas manifold having at least two first gas connection fittings connecting corresponding amount of substrate tubes to the apparatus, the first gas manifold being provided in a flow communication with the inlet tube for supplying the first precursor and the second precursor from the inlet tube into the substrate tubes, and a second gas manifold having at least two second gas connection fittings connecting corresponding amount of substrate tubes to the apparatus, the second gas manifold being provided in a flow communication with the outlet tube for discharging the first precursor and the second precursor that have been supplied through the substrate tubes. The method further comprises the step of: connecting at least two substrate tubes to the first gas connection fittings and to the second gas connection fittings so that the at least two substrate tubes extend between the first gas manifold and the second gas manifold; supplying the first precursor from the inlet tube to the first gas manifold and supplying the first precursor from the first gas manifold simultaneously into the at least two substrate tubes; discharging the first precursor supplied through the at least two substrate tubes from the second gas manifold to the outlet tube; supplying the second precursor from the inlet tube to the first gas manifold and supplying the second precursor from the first gas manifold simultaneously into the at least two substrate tubes; and discharging the second precursor supplied through the at least two substrate tubes from the second gas manifold to the outlet tube.

In other words, multiple substrate tubes are connected to the apparatus such that the first open end of the substrate tubes is connected to the first gas connection fitting of the first gas manifold and the second open end of the substrate tubes is connected to the second gas connection fitting of the second gas manifold opposite to the first gas manifold. The first gas connection fitting connects the substrate tube to the first gas manifold and forms a flow connection between the inlet tube and the substrate tube through the first gas manifold, and the second gas connection fitting connects the substrate tube to the second gas manifold and forms a flow connection between the outlet tube and the substrate tube through the second gas manifold. The substate tubes connected at their both ends to the apparatus form multiple reaction chambers of the atomic layer deposition apparatus of the invention. The coating to the inner surface of the substrate tubes connected to the apparatus is formed by supplying the first precursor from the inlet tube to the first gas manifold in which it is then divided in the first gas manifold to be supplied simultaneously through the multiple substrate tubes and discharging the first precursor through the second gas manifold and through the outlet tube and then supplying the second precursor similarly, i.e., supplying the second precursor from the inlet tube to the first gas manifold in which it divides to be supplied simultaneously through the multiple substrate tubes and discharging the second precursor through the second gas manifold and finally through the outlet tube. Thereby the coating is formed all over the inner surfaces of the substrate tubes.

According to the invention the method further comprises the step of arranging the at least two substrate tubes parallel in the atomic layer deposition apparatus or arranging the at least two substrate tubes parallel in the atomic layer deposition apparatus inside a vacuum chamber.

In other words, the apparatus may comprise multiple substrate tubes to be coated simultaneously which the substrate tubes are arranged side by side in the atomic layer deposition apparatus. The multiple substrate tubes forming multiple reaction chambers when being connected to the apparatus and arranged into the vacuum chamber for coating the inner surfaces of the substrate tubes.

According to the invention the atomic layer deposition apparatus comprising a first gas manifold having at least two first gas connection fittings connecting corresponding amount of substrate tubes to the apparatus, the first gas manifold being provided in a flow communication with the inlet tube for supplying the first precursor and the second precursor from the inlet tube into the substrate tubes, a second gas manifold having at least two second gas connection fittings connecting corresponding amount of substrate tubes to the apparatus, the second gas manifold being provided in a flow communication with the outlet tube for discharging the first precursor and the second precursor that have been supplied through the substrate tubes, and an adapter module placed between the first gas manifold and the second gas manifold in the apparatus, the adapter module having corresponding gas connection fittings for the substrate tubes extending from the first gas manifold for connecting the substrate tubes to the adapter module, and corresponding gas connection fittings for substrate tubes extending from the adapter module to the second gas manifold, thereby providing a flow path for precursors from the inlet tube through the substrate tubes to adapter module and further through successive substrate tubes to the outlet tube. The method further comprises the steps of: connecting at least two substrate tubes to the first gas connection fittings of the first gas manifold and to the second gas connection fittings of the adapter module so that the at least two substrate tubes extend between the first gas manifold and the adapter module; connecting at least two substrate tubes to the first gas connection fittings of the adapter module and to the second gas connection fittings of the second gas manifold so that the at least two substrate tubes extend between the adapter module and the second gas manifold; supplying the first precursor from the inlet tube to the first gas manifold and supplying the first precursor from the first gas manifold simultaneously into the at least two substrate tubes and through the adapter module into the successive at least two substrate tubes; discharging the first precursor that has been supplied through the at least two substrate tubes and through the adapter module and further through the successive substrate tubes from the second gas manifold to the outlet tube; supplying the second precursor from the inlet tube to the first gas manifold and supplying the second precursor from the first gas manifold simultaneously into the at least two substrate tubes and through the adapter module into the successive at least two substrate tubes; and discharging the second precursor that has been supplied through the at least two substrate tubes and through the adapter module and further through the successive substrate tubes from the second gas manifold to the outlet tube.

In other words, the adapter module is arranged between the first and second gas manifolds and provides similar gas connection fittings as the first and second gas manifold. The adapter module having the second gas connection fittings facing toward the first gas connection fittings of the first gas manifold, and the adapter module having the first gas connection fittings at the opposite side of the adapter module than the second gas connection fittings, which the first gas connection fittings of the adapter module facing toward the second gas connection fittings of the second gas manifold. The adapter module provides a flow path inside the adapter module between the second gas connection fittings and the first gas connection fittings such that the precursor flow from the inlet tube through first gas manifold and the substrate tube flows through the adapter module to the successive substrate tube and finally through the second gas manifold to the outlet tube.

According to the invention the method as described above is performed with the atomic layer deposition apparatus according to what is describe before in this description.

An advantage of the invention is that the coating can be applied to the entire inner surface of the substrate tube, but it is not applied anywhere else, for example, the outer surface of the tube remains clean, and no coating is produced anywhere else on the apparatus.

### BRIEF DESCRIPTION OF THE DRAWINGS

The invention is described in detail by means of specific embodiments with reference to the enclosed drawings, in which

FIG. 1 shows an atomic layer deposition apparatus according to the invention;

FIG. 2 shows another example of an atomic layer deposition apparatus according to the invention;

FIG. 3 shows the atomic layer deposition apparatus shown in FIG. 2 as seen from above; and

FIG. 4 show yet another example of an atomic layer deposition apparatus according to the invention.

### DETAILED DESCRIPTION OF THE INVENTION

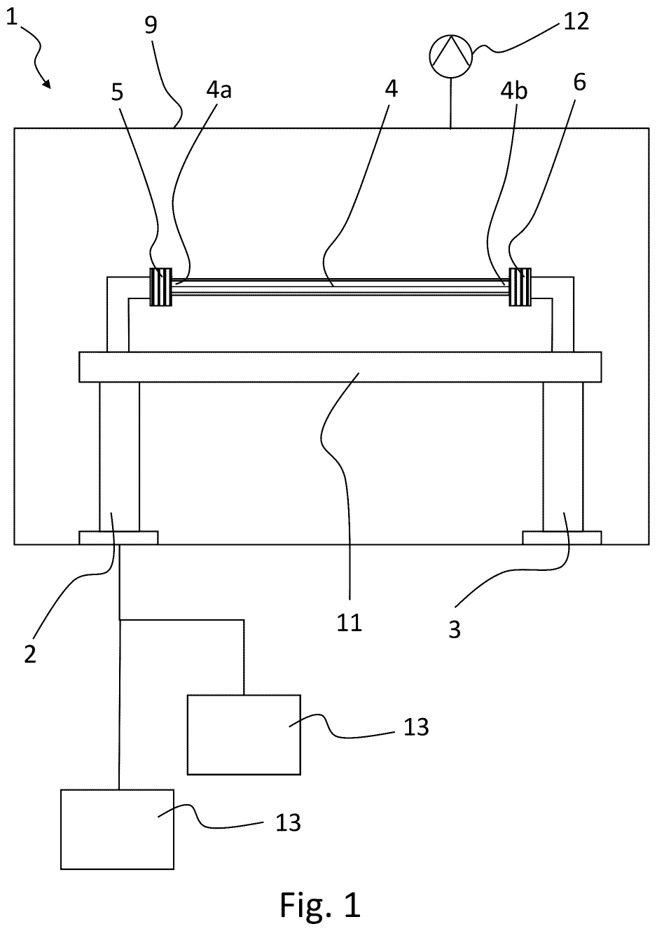

FIG. 1 shows an atomic layer deposition apparatus 1 according to the invention which comprises an inlet tube 2 for supplying precursor gases from precursor gas sources 13 to a first gas connection fitting 5 and an outlet tube 3 for discharging precursor gases out of the apparatus 1. The inlet tube 2 and the outlet tube 3 are provided in connection with a frame structure 11. Although the FIG. 1 shows that the inlet tube 2 and the outlet tube 3 end at the frame structure 11 the piping connecting the inlet tube 2 to the first gas connection fitting 5 extend such that the first gas connection fitting 5 is in a flow communication with the inlet tube 2. The same applies to the outlet tube 3 and the second gas connection fitting 6 so that the second gas connection fitting 6 is in a flow communication with the outlet tube 3. The precursor gas sources 13 are marked with the same reference number as it is irrelevant for the sake of features of this invention which one contains the first precursor gas, and which one contains the second precursor gas. The first gas connection fitting 5 is receiving a first end 4a of the substrate tube 4 and connecting the substrate tube 4 from its first end 4a to the apparatus 1. The second gas connection fitting 6 is receiving a second end 4b of the substrate tube 4 and connecting the substrate tube 4 from its second end 4b to the apparatus. The apparatus 1 further comprising a vacuum chamber 9 comprising a vacuum pump 12 arranged to provide vacuum conditions to the vacuum chamber 9. In the processing state the substrate tube 4 connected to the first gas connection fitting 5 and to the second gas connection fitting is provided inside the vacuum chamber 12 and is arranged to form a reaction chamber of the atomic layer deposition apparatus 1, the first gas connection fitting 5 being in a flow communication with the inlet tube 2 and the second gas connection fitting 6 being in a flow communication with the outlet tube 3.

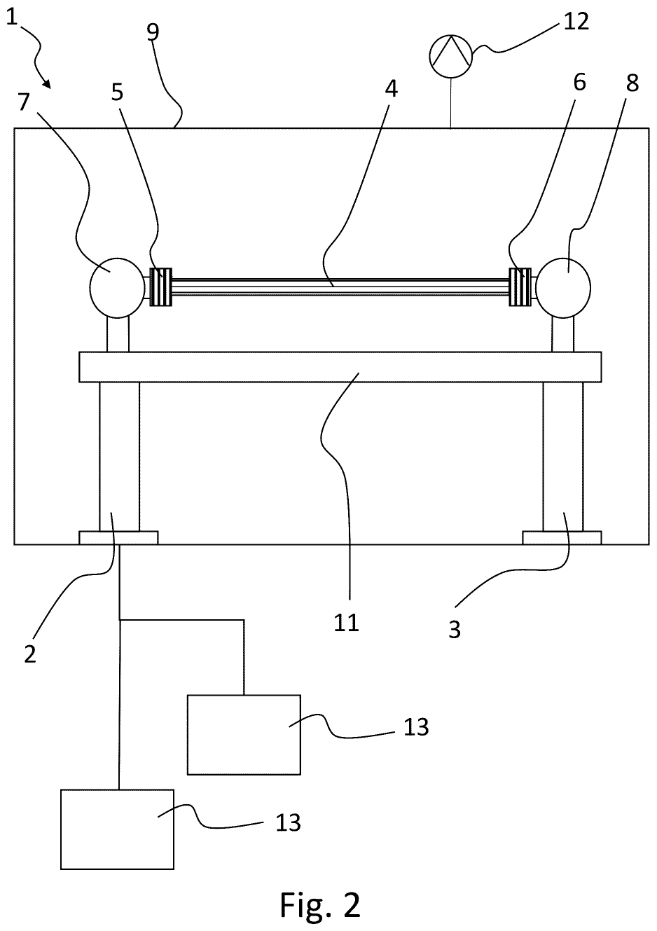

FIG. 2 shows another example of an atomic layer deposition apparatus 1 according to the invention in which the first gas connection fitting 5 is provided at a first gas manifold 7 which is in a flow communication with the inlet tube 2, and the second gas connection fitting 6 is provided at a second gas manifold 8 which is in a flow communication with the outlet tube 3. The substrate tube 4 is arranged to form the reaction chamber of the apparatus 1 by being connected to the first gas connection fitting 5 and to the second gas connection fitting 6 and thereby extending between the first gas manifold 7 and the second gas manifold 8. Otherwise, the features of the invention are as described in connection with the FIG. 1.

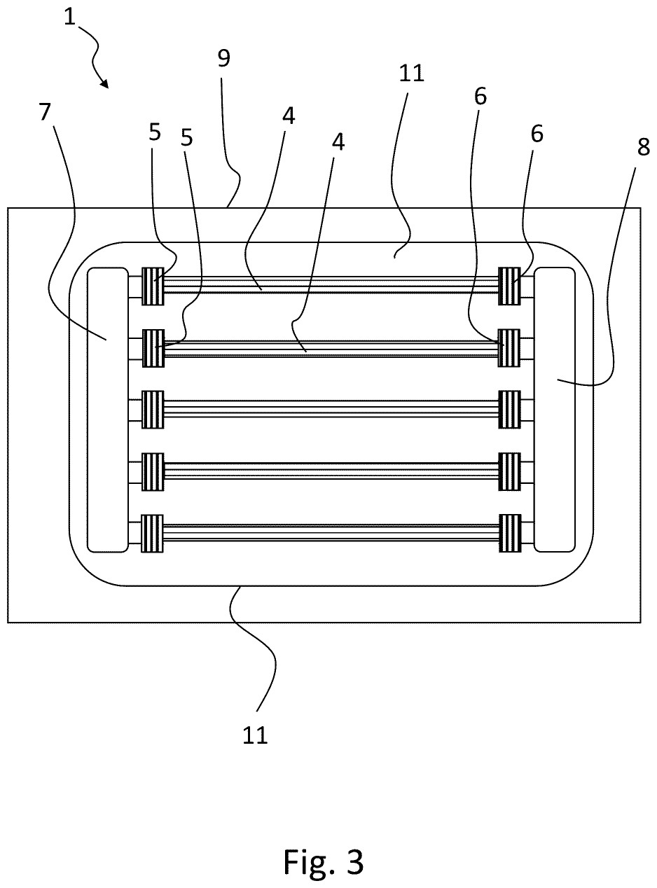

FIG. 3 shows the atomic layer deposition apparatus 1 shown in FIG. 2 as seen from above. The FIG. 3 shows that there are multiple substrate tubes 4 arranged side by side, and in this example also parallel, between the first gas manifold 7 and the second gas manifold 8. The substrate tubes 4 are connected from their ends to the gas manifolds 7, 8 with gas connection fittings 5, 6. The first gas connection fitting 5 connecting the substrate tube 4 at its first end 4a and the second gas connection fitting 6 connecting the substrate tube 4 at its second end 4b to the apparatus 1. Although the FIG. 3 shows only 5 substrate tubes 4 placed side by side with each other to the apparatus 1, there can be also other amounts of substrate tubes 4 connected to the apparatus for simultaneous coating. The substrate tubes 4 can also be provided on different levels next to each other, so that the substrate tubes 4 are arranged both next to each other and on top of each other extending between the first and second gas manifold 7, 8.

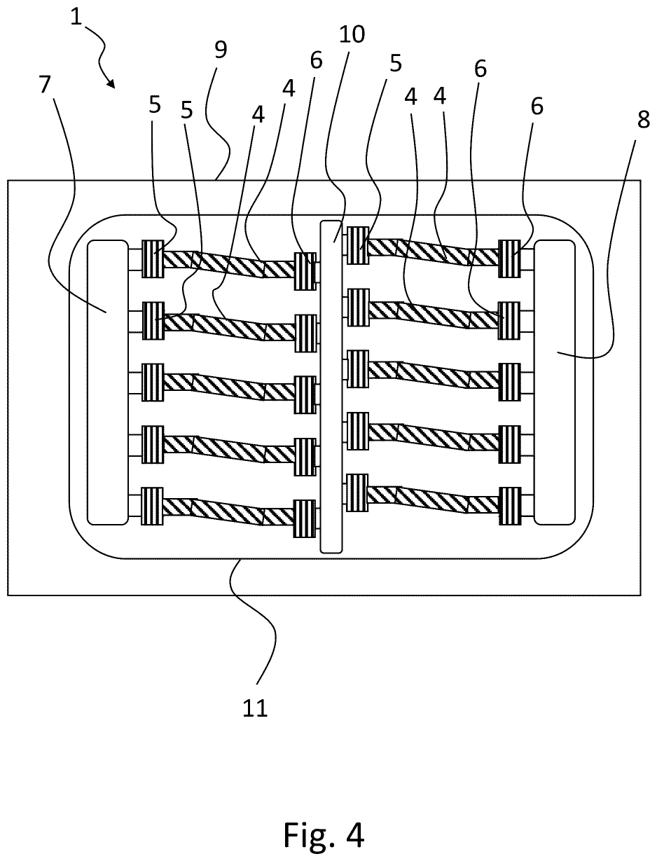

FIG. 4 show yet another example of an atomic layer deposition apparatus 1 according to the invention in which an adapter module 10 is provided between the first gas manifold 7 and the second gas manifold 8. The adapter module 10 is arranged to provide more substrate tubes 4 to the apparatus 1 for simultaneous coating of the inner surfaces of the substrate tubes 4. The adapter module 10 has the second gas connection fittings 6 facing toward the first gas connection fittings 4 of the first gas manifold 7, and the adapter module 10 has the first gas connection fittings 5 at the opposite side of the adapter module 10 than the second gas connection fittings 6, which the first gas connection fittings 5 of the adapter module 10 facing toward the second gas connection fittings 6 of the second gas manifold 8. As can be seen from the FIG. 4 the first and second gas connection fittings 5, 6 may not need to be directly opposite each other, especially when the substrate tubes 4 are not straight but can comprise, for example, a bend or a fold. The first and second gas manifolds 7, 8 are fixed to the frame structure 11 that also supports a support plate or similar surface structure on which flexible substrate tubes can be stacked rather than leaving them dangling.

The invention has been described above with reference to the examples shown in the figures. However, the invention is in no way restricted to the above examples but may vary within the scope of the claims.

1. An atomic layer deposition apparatus for processing an inner surface of a substrate tube successively with at least a first precursor and a second precursor according to principles of atomic layer deposition, the apparatus comprising:
a first gas connection fitting arranged to receive a first end of the substrate tube and to connect the substrate tube from its first end to the apparatus;
a second gas connection fitting arranged to receive a second end of the substrate tube and to connect the substrate tube from its second end to the apparatus;
an inlet tube arranged to supply the first precursor and the second precursor from corresponding gas sources into the substrate tube, the first gas connection fitting being in a flow communication both with the inlet tube and the substrate tube and providing a flow communication between the inlet tube and the substrate tube; and
an outlet tube arranged to discharge the first precursor and the second precursor that have been supplied through the substrate tube, the second gas connection fitting being in a flow communication both with the outlet tube and the substrate tube and providing a flow communication between the substrate tube and the outlet tube.

2. The atomic layer deposition apparatus according to claim 1, further comprising:
a first gas manifold having at least two first gas connection fittings for connecting corresponding amount of substrate tubes to the apparatus, the first gas manifold being provided in a flow communication with the inlet tube for supplying the first precursor and the second precursor from the gas sources through the inlet tube into the substrate tubes; and
a second gas manifold having at least two second gas connection fittings for connecting corresponding amount of substrate tubes to the apparatus, the second gas manifold being provided in a flow communication with the outlet tube for discharging the first precursor and the second precursor that have been supplied through the substrate tube.

3. The atomic layer deposition apparatus according to claim 1, wherein the substrate tube connected to the apparatus with the first gas connection fitting and the second gas connection fitting and extending between the first gas connection fitting and the second gas connection fitting is arranged to form a reaction chamber of the atomic layer deposition apparatus.

4. The atomic layer deposition apparatus according to claim 1, further comprising an adapter module arranged to be placed between the first gas connection fitting and the second gas connection fitting in the apparatus to enable connecting of substrate tubes successively between the first and second gas connection fittings, the adapter module having corresponding gas connection fittings for the substrate tubes and provides a flow path for supplying precursors from the inlet tube through the adapter module to the outlet tube when the substrate tubes are connected to the gas connection fittings.

5. The atomic layer deposition apparatus according to claim 1, further comprising a vacuum chamber comprising interface connections for the inlet tube and for the outlet tube.

6. The atomic layer deposition apparatus according to claim 1, further comprising a frame structure,
wherein the inlet tube is in the flow communication with the first gas connection fitting, and the outlet tube is in the flow communication with the second gas connection fitting are arranged in a frame structure.

7. An atomic layer deposition apparatus according to claim 5, wherein the frame structure is arranged to be movable so that it can be moved into and out of the vacuum chamber.

8. A method for subjecting an inner surface of a substrate tube to successive surface reactions of at least a first precursor and a second precursor according to principles of atomic layer deposition in an atomic layer deposition apparatus for forming a coating to the inner surface of the substrate tube, the method comprising:
providing the substrate tube to the apparatus and connecting the substrate tube from its first end to a first gas connection fitting provided in a flow communication with an inlet tube and from its second end to a second gas connection fitting provided in a flow communication with an outlet tube; and
forming a coating to the inner surface of the substrate tube by:
subjecting the inner surface of the substrate tube with the first precursor by supplying the first precursor from the inlet tube through the substrate tube and discharging the first precursor supplied through the substrate tube to the outlet tube; and
subjecting the inner surface of the substrate tube with the second precursor by supplying the second precursor from the inlet tube through the substrate tube and discharging the second precursor supplied through the substrate tube to the outlet tube.

9. The method according to claim 8, wherein the atomic layer deposition apparatus comprises:
a first gas manifold having at least two first gas connection fittings connecting corresponding amount of substrate tubes to the apparatus, the first gas manifold being provided in a flow communication with the inlet tube for supplying the first precursor and the second precursor from the inlet tube into the substrate tubes; and
a second gas manifold having at least two second gas connection fittings connecting corresponding amount of substrate tubes to the apparatus, the second gas manifold being provided in a flow communication with the outlet tube for discharging the first precursor and the second precursor that have been supplied through the substrate tubes,
wherein the method further comprises:
connecting at least two substrate tubes to the first gas connection fittings extend between the first gas manifold and the second gas manifold;
supplying the first precursor from the inlet tube to the first gas manifold and supplying the first precursor from the first gas manifold simultaneously into the at least two substrate tubes;
discharging the first precursor supplied through the at least two substrate tubes from the second gas manifold to the outlet tube;
supplying the second precursor from the inlet tube to the first gas manifold and supplying the second precursor from the first gas manifold simultaneously into the at least two substrate tubes; and
discharging the second precursor supplied through the at least two substrate tubes from the second gas manifold to the outlet tube.

10. The method according to claim 9, further comprises:
arranging the at least two substrate tubes parallel in the atomic layer deposition apparatus; or
arranging the at least two substrate tubes parallel in the atomic layer deposition apparatus inside a vacuum chamber.

11. The method according to claim 8, wherein the atomic layer deposition apparatus comprises:
a first gas manifold having at least two first gas connection fittings connecting corresponding amount of substrate tubes to the apparatus, the first gas manifold being provided in a flow communication with the inlet tube for supplying the first precursor and the second precursor from the inlet tube into the substrate tubes;
a second gas manifold having at least two second gas connection fittings connecting corresponding amount of substrate tubes to the apparatus, the second gas manifold being provided in a flow communication with the outlet tube for discharging the first precursor and the second precursor that have been supplied through the substrate tubes; and
an adapter module placed between the first gas manifold and the second gas manifold in the apparatus, the adapter module having corresponding gas connection fittings for the substrate tubes extending from the first gas manifold for connecting the substrate tubes to the adapter module, and corresponding gas connection fittings for substrate tubes extending from the adapter module to the second gas manifold, thereby providing a flow path for precursors from the inlet tube through the substrate tubes to adapter module and further through successive substrate tubes to the outlet tube,
wherein the method further comprises:
connecting at least two substrate tubes to the first gas connection fittings of the first gas manifold and to the second gas connection fittings of the adapter module so that the at least two substrate tubes extend between the first gas manifold and the adapter module;
connecting at least two substrate tubes to the first gas connection fittings of the adapter module and to the second gas connection fittings of the second gas manifold so that the at least two substrate tubes extend between the adapter module and the second gas manifold;
supplying the first precursor from the inlet tube to the first gas manifold and supplying the first precursor from the first gas manifold simultaneously into the at least two substrate tubes and through the adapter module into the successive at least two substrate tubes;
discharging the first precursor that has been supplied through the at least two substrate tubes and through the adapter module and further through the successive substrate tubes from the second gas manifold to the outlet tube;
supplying the second precursor from the inlet tube to the first gas manifold and supplying the second precursor from the first gas manifold simultaneously into the at least two substrate tubes and through the adapter module into the successive at least two substrate tubes; and
discharging the second precursor that has been supplied through the at least two substrate tubes and through the adapter module and further through the successive substrate tubes from the second gas manifold to the outlet tube.

12. (canceled)
